(19) United States
(12) Patent Application Publication
(10) Pub. No.: US 2012/0018704 A1
(43) Pub. Date: Jan. 26, 2012

(54) UNIAXIAL TENSILE STRAIN IN SEMICONDUCTOR DEVICES

(75) Inventors: David John Wallis, Malvern (GB); Richard Jefferies, Malvern (GB)

(73) Assignee: QINETIQ LIMITED, Farnborough, Hampshire (GB)

(21) Appl. No.: 13/263,621

(22) PCT Filed: Apr. 12, 2010
(86) PCT No.: PCT/GB10/00713

§ 371 Date: Oct. 7, 2011

(30) Foreign Application Priority Data
Apr. 14, 2009 (GB) 0906333.0

(51) Int. Cl. H01L 29/78; H01L 21/20

(52) U.S. Cl. 257/24; 438/478; 257/E21.09; 257/E29.255

(57) ABSTRACT

A semiconductor device structure comprises an active layer and a buffer layer. The active layer is a quantum well structure. There is a lattice mismatch between the buffer layer and the active layer which places the active layer under biaxial compressive strain. Uniaxial tensile strain is applied to the active layer to reduce compressive strain on the active layer in a second direction but not in a first direction. This favours hole and electron mobility in the first direction, rendering the semiconductor device structure suitable for the formation of both p-channel and n-channel devices.

### FIELD OF THE INVENTION

The invention relates to uniaxial tensile strain in semiconductor devices, especially Group III-V semiconductor devices. It is particularly relevant to uniaxial tensile strain in semiconductor devices with a quantum well active layer, in particular QWFETs (Quantum Well Field Effect Transistors).

### BACKGROUND TO THE INVENTION

In order to produce improvements to logic circuits, it is desirable to produce device structures, particularly field-effect transistors (FETs), that work at higher frequencies and lower powers. The standard architecture for digital circuit design is CMOS. To achieve CMOS circuits, both n-FETs (with electrons as charge carriers) and p-FETs (with holes as charge carriers) are required.

Conventional CMOS design is largely based on Si semiconductor technology. For n-FETs, very high operational frequencies and low operating powers have been achieved using InSb as a semiconductor. In this system, a layer of AlₓIn₁₋ₓSb is grown on a suitable substrate, such as GaAs, and a thin device layer of InSb grown over this. A donor layer to provide electrons is grown over the device layer, separated from it by a small AlₓIn₁₋ₓSb spacer layer. The device layer is capped by a suitable layer, again AlₓIn₁₋ₓSb, to confine the charge carriers in the device layer region, which forms a quantum well. For regions with a composition of AlₓIn₁₋ₓSb, the value of x may vary from region to region. There is a lattice mismatch between the InSb and the AlₓIn₁₋ₓSb, which leads to biaxial strain in the quantum well and can result in increased carrier mobility. InSb has a very high electron mobility, and extremely good results have been achieved.

It is desirable to be able to produce p-FETs with comparable performance to these InSb n-FETs. InSb has relatively high hole mobility, so the same InSb/AlₓIn₁₋ₓSb system is an appropriate one for producing p-FETs with suitable properties. The strain in the quantum well structure makes a significant contribution to these electrical properties. The quantum well structure is under significant biaxial compressive strain as a result of the lattice mismatch between InSb and AlₓIn₁₋ₓSb. It is known that strain can make a significant contribution to carrier mobility. In Si surface channel devices, it is found that tensile strain in the carrier transport direction enhances electron mobilities, whereas compressive strain in the carrier transport direction enhances hole mobilities.

It would be desirable to use the benefits of strain to provide improved device structures. However, it is necessary to do this in such a way that the devices remain stable, and do not break down or lose desirable electrical properties through the presence of excessive strain.

### SUMMARY OF THE INVENTION

Accordingly, in a first aspect the invention provides a semiconductor device structure comprising: an active layer comprising a quantum well structure; a buffer layer underneath and adjacent to the active layer, wherein there is a lattice mismatch between the buffer layer and the active layer which places the active layer under biaxial compressive strain; and means to apply uniaxial tensile strain to the active layer to reduce compressive strain on the active layer in a second direction but not in a first direction, the first direction and the second direction lying in a plane of the active layer.

The semiconductor device structure may be a precursor structure for a device such as a field-effect transistor, the precursor taking the form of an epitaxially layered structure comprising buffer and active layers as described herein. The precursor structure may comprise a p-channel or an n-channel, depending on the desired final device. Optionally, the precursor structure may comprise a temporary or permanent cap layer, suitable capping materials being well known to the skilled person.

The arrangement of the invention enables the high carrier mobility resulting from compressive strain to be exploited in the first direction, without there being such significant strain on the active layer that physical deterioration will result with decline in electrical properties. This may be applied to both p-type and n-type devices.

Advantageously, both p-channel devices such as p-FETs (or precursor structures thereof) and n-channel devices such as n-FETs (or precursor structures thereof) are formed with the respective p-channel or n-channel lying in the first direction. This approach thus allows improved fabrication of p-FET and n-FET structures (or precursor structures thereof) on the same substrate using the same semiconductor device system.

Typically, the second direction will be substantially perpendicular to the first direction, in the plane of the active layer. Hence, the uniaxial tensile strain is typically applied orthogonal to the direction of current flow in the active layer.

The active part of the device may be unstrained in the second direction, as the uniaxial tensile strain and the biaxial compressive strain are in balance. Alternatively, the uniaxial tensile strain may exceed the biaxial compressive strain, and the semiconductor device structure may be under overall tensile strain in the second direction, leading to greater carrier mobility in the first direction than for the bulk semiconductor.

Desirably, the active layer is formed of InSb and the buffer layer of AlₓIn₁₋ₓSb, though alternative semiconductor systems may be employed.

In a further aspect, the invention provides a method of manufacturing a semiconductor device structure, comprising: epitaxially growing a buffer layer on a substrate; epitaxially growing a quantum well active layer on the substrate, wherein there is a lattice mismatch between the buffer layer and the active layer which places the active layer under biaxial compressive strain; and applying uniaxial tensile strain to the active layer to reduce compressive strain on the active layer in a second direction but not in a first direction, the first direction and the second direction lying in a plane of the active layer.

The uniaxial tensile strain may be applied to the semiconductor device structure as a whole. This may be done by a mechanical approach, such as by bending the semiconductor device structure about an axis lying in the first direction or by stretching the semiconductor device structure in the second direction. This may occur before or after bonding the semiconductor device to a base substrate.

Any feature in one aspect of the invention may be applied to any other aspects of the invention, in any appropriate combination. In particular, device aspects may be applied to method and use aspects, and vice versa. The invention extends to a device and method substantially as herein described, with reference to the accompanying drawings.

### SPECIFIC EMBODIMENTS OF THE INVENTION

Specific embodiments of the invention will now be described, by way of example, by reference to the accompanying Figures, of which:

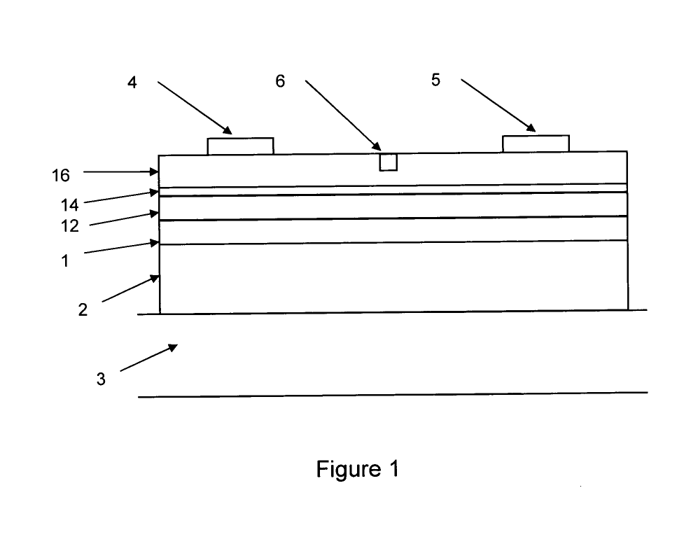

FIG. 1 shows an FET structure which can be used in embodiments of the invention;

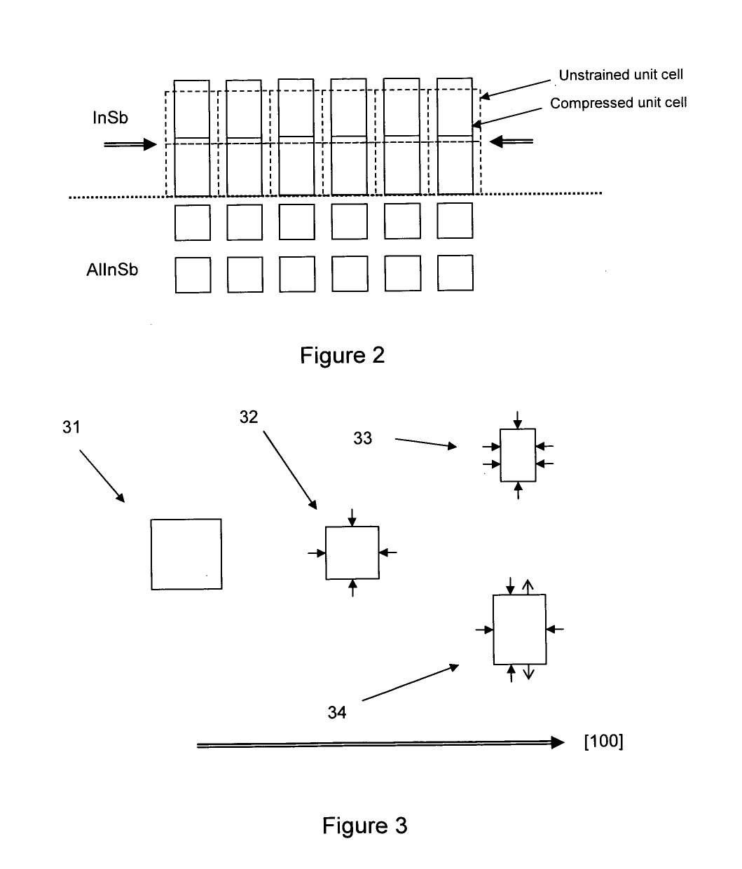

FIG. 2 illustrates the compressive biaxial strain on the active layer in a strained quantum well device;

FIG. 3 illustrates the effect of applying uniaxial tensile strain to a strained quantum well device in accordance with embodiments of the invention; and

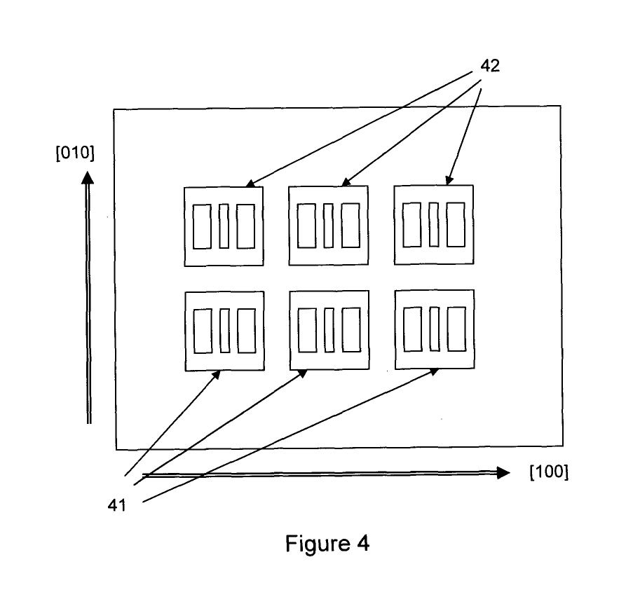

FIG. 4 illustrates n-FET and p-FET devices formed from a strained quantum well active layer under uniaxial tensile strain in accordance with embodiments of the invention.

FIG. 1 shows a device structure which can be used either for an n-FET device or a p-FET device with appropriate materials and design choices.

The device structure has an InSb quantum well active layer 1 grown on an AlₓIn₁₋ₓSb buffer layer 2. It is appreciated that similar structures can be produced for other III-V semiconductor systems or indeed other semiconductor systems altogether using a strained quantum well structure. The buffer layer is grown on a substrate 3, which may for example be of GaAs (though Si is a possible alternative). The buffer layer 2 is typically about 3 μm thick, though this thickness may be reduced to as little as 1 μm in appropriate embodiments, and its composition is chosen to provide effective containment of the charge carriers in the active layer 1—for AlₓIn₁₋ₓSb, this could involve a value for x of approximately 0.35 for p-FETs and 0.15 for n-FETs (electrons show stronger confinement than holes, so the two device systems optimise differently). The lattice mismatch between InSb and AlₓIn₁₋ₓSb places the active layer 1 under compressive strain—this strain is approximately 2% for Al_{0.35}In_{0.65}Sb.

The active layer 1 may differ in thickness for different device types. There may also be different materials choices in the other device layers.

For an n-FET, the active layer 1 may be approximately 20 nm thick—at this thickness quantum states for the carriers are abundant. A spacer layer 12 of AlₓIn₁₋ₓSb is provided above the active layer, and above that there is a donor sheet 14 (which may, for example, comprise a Te δ-doped sheet doped at approximately 1×10¹² cm⁻²) to provide electrons as carriers for the n-channel of the n-FET. This is covered by a confinement layer 16 of AlₓIn₁₋ₓSb to confine charge carriers in the quantum well structure—this may be 15-45 nm thick.

For a p-FET, a thinner active layer may be used as dislocations resulting from the lattice mismatch would severely limit hole mobility. A quantum well thickness of about 5 nm is sufficiently thin that dislocations will not limit hole mobility, but sufficiently thick that there are sufficient low energy quantum states available for carriers. A spacer layer 12 of AlₓIn₁₋ₓSb is again provided above the active layer with a composition suitable for a p-channel. Above this there is a donor sheet 14 with a dopant appropriate for a p-channel (this may, for example, comprise a Be δ-doped sheet) to provide holes as carriers for the p-channel. This is again covered by a confinement layer 16 of AlₓIn₁₋ₓSb to confine charge carriers in the quantum well structure.

The source 4, the drain 5 and the gate 6 of each FET are formed over the confinement layer 16 in each case by an appropriate metallisation process. This may be a conventional photolithographic or e-beam lithographic process of masking and etching. It is necessary for the gate 6 to have control over conduction in the channel formed in the active layer 1 between the source 4 and the drain 5—this requires that it is not separated by too great a thickness of insulator/wider band gap semiconductor from the active layer 1. FIG. 1 shows an arrangement in which the confinement layer 16 has been etched back underneath the gate to allow the gate voltage to control the n-channel/p-channel effectively.

Further device structures may be employed in other embodiments of the invention—what is shown in FIG. 1 is simply a suitable device structure for use with this materials system. The person skilled in the art will appreciate that other structures may be used for this materials system, or may be appropriate with other materials systems. As indicated above, the n-FET and p-FET structures here are only examples of device structures that may be used in embodiments of the invention, and alternative device structures may similarly be used. One example of such an alternative device structure suitable for p-FETs is a system using α-Sn as semiconductor, rather than InSb (as is discussed in the applicant's British patent application GB 0906336.3 and co-pending PCT application of even date entitled “P-Type Semiconductor Devices”, which is incorporated by reference herein to the extent permitted by law. A further example suitable for p-FETs is one in which the thickness of the active layer is increased by compensating for strain in the buffer layer caused by thermal expansion and lattice mismatches between the buffer layer and the substrate—this is described in more detail in the applicant's British patent application GB 0906331.4 and co-pending PCT application of even date entitled “Strain Control in Semiconductor Devices”, which is incorporated by reference herein to the extent permitted by law.

FIG. 2 illustrates the biaxial compressive strain on the active layer. Both InSb and AlₓIn₁₋ₓSb adopt the zincblende crystal structure, but the unit cell of InSb is significantly larger than that of AlₓIn₁₋ₓSb, resulting in a lattice mismatch between the two and a compressive strain of almost 2% on the InSb quantum well structure as it is constrained to the AlₓIn₁₋ₓSb dimensions with x=0.35. This compressive strain is broadly beneficial for p-type devices, as it promotes hole transport. Holes therefore have a high mobility in this kind of quantum well structure, provided that the quantum well itself is sufficiently thin, as the high compressive strain will result in dislocations if the quantum well exceeds a critical thickness (approximately 7 nm for InSb on Al_{0.35}In_{0.65}Sb, according to the model set out in Matthews and Blakeslee, set out in Journal of Crystal Growth Vol. 29 (1975) pp. 273-280).

This arrangement favours the formation of p-type devices. In suitable materials systems, such as the InSb system discussed here, it is found also to be advantageous for n-type devices, as it has been found that electron mobility is also favoured by tensile strain in such systems.

If uniaxial strain is applied to the device, a first direction and a second direction will be established—one without strain, and the other with strain. Electron and hole mobility will be favoured in the nominally unstrained direction. If uniaxial compressive strain is applied in the first direction, hole and electron mobility will in principle be further enhanced in this direction. This, however, increases the level of strain to a very high value, as 2% strain is already a significant amount to be accommodated in a crystal structure. Use of such high values of strain would increase the risk of physical breakdown of the material with consequent damage to the electrical properties of the device.

Applying uniaxial tensile strain to the first direction achieves a more effective result, as is shown in plan view in FIG. 3 which illustrates an embodiment of the invention in schematic terms. A unit cell of InSb is shown under different conditions. In the bulk, the unit cell (31) is unstrained, but in a quantum well structure (32) grown on Al_{0.35}In_{0.65}Sb, it is under 2% compressive strain. As indicated above, when uniaxial compressive strain is applied (33) in the direction of current flow—this may be chosen as the [100] or [110] direction in this semiconductor system—this increases hole and electron mobility in principle, but leads to potential material breakdown. However, when uniaxial tensile strain is applied (34) substantially perpendicular to the channel current flow direction in a plane of the active layer—along the [010] or [110] direction in this case—the carrier mobility in the channel remains high and will moreover be higher in the current flow direction than in a direction orthogonal to current flow. The level of uniaxial tensile strain may be chosen to make the overall strain in the [010] or [110] direction substantially zero, or even sufficient to make the overall strain in the [010] or [110] direction tensile rather than compressive.

As shown in FIG. 4, this favours the formation on the semiconductor device structure of both p-FETs (41) (and other p-channel devices) and n-FETs (42) (and other n-channel devices) in the same orientation, with the channels lying in the [100] direction. This allows enhanced hole and electron mobility to be achieved together in a single semiconductor system.

There are a variety of different approaches available for applying uniaxial strain to semiconductor devices. These include mechanical approaches, growth of different materials near the device, and use of compliant substrates. Each approach will be briefly described, though it will be appreciated that any approach to applying uniaxial tensile strain which does not damage the fundamental electrical properties of the device may be applied, and that the approaches shown here are by way of example only.

A range of mechanical approaches for producing uniaxial tensile strain to a semiconductor device are discussed in U.S. Pat. No. 6,455,397. All these techniques may be applied to a semiconductor device structure which has already been grown (referred to in U.S. Pat. No. 6,455,397 as a “membrane”), though thinning of the device substrate below a conventional thickness may be required to make the techniques effective. In a first approach, the membrane is mechanically stretched by clamping to a strain bed and applying tensile strain by a screw and micrometer assembly. The strained membrane is then bonded to an additional substrate while under tension. In a second approach, the membrane is mounted and bonded to a curved additional substrate, the curvature being chosen to achieve a particular strain value. In a third approach, an additional substrate is positioned within the curvature of a curved support structure. The membrane is then bonded to this additional substrate—the additional substrate and membrane are then removed from the support structure and the additional substrate is bonded to a substantially flat surface of a further additional substrate. All these approaches allow the application of controlled uniaxial tensile strain to a semiconductor device structure of the type described here. Further details of the straining processes outlined here are not in themselves fundamental to the present invention, but may be found in U.S. Pat. No. 6,455,397.

Use of growth of different materials near a semiconductor device to induce strain in that device is known, but is generally used as a mechanism to introduce compressive strain (by growing a region that presses against the device region to compress it further). Other approaches involving this type of technique are however discussed in Ghani et al, Technical Digest of the International Electron Devices Meeting 2003, 8 (2003), and the person skilled in the art will appreciate that this approach may also be used to provide uniaxial tensile strain.

Use of compliant substrates to apply uniaxial tensile strain is discussed in Yin et al, Applied Physics Letters 87, 061922 (2005). After growth, semiconductor devices are transferred to a substrate coated with a compliant film (in the case described, a borophosphosilicate glass (BPSG) film formed on a Si substrate). The device structure is patterned into islands, and heating of the assembled structure allows for change in strain as the viscosity of the BPSG film decreases rapidly with temperature. This approach again allows for application of tunable uniaxial tensile strain, and is further described in Yin et al.

A method of making such a semiconductor device structure can employ conventional approaches to formation of the basic device structure together with a method of applying tensile uniaxial strain as discussed above. A buffer layer is grown over the substrate using a suitable epitaxial growth method—molecular beam epitaxy (MBE) and metalorganic chemical vapour deposition (MOCVD) are particularly suitable epitaxial growth techniques, but any suitable growth technique may be used (other examples are MOVPE, ALD and MECVD). Growth by MBE or MOCVD at a suitable temperature (effective growth can be achieved at 350° C., but growth can be carried out up to the melting point of InSb at 520° C.) is appropriate for growth of AlₓIn₁₋ₓSb on GaAs, but as the skilled person will appreciate, other epitaxial growth methods may be used. The InSb quantum well structure may be grown over this by a similar growth method, as may the other insulator and dopant layers by processes well established in the technical literature. Metallisation to form the source, the drain and the gate of each FET structure (alternative metallisations may be required for other device structures, but the same principles apply) may be made by any appropriate approach, such as photolithographic mask and etch processes. A process for applying uniaxial tensile strain may be employed either after fabrication or during fabrication of the semiconductor device structure, depending on which is appropriate to the strain producing process used. For example, for any of the mechanical processes described in U.S. Pat. No. 6,455,397, the basic semiconductor device structure would be formed before uniaxial tensile strain is applied, the strain subsequently being applied by one of the processes described in U.S. Pat. No. 6,455,397.

1. A semiconductor device structure comprising:
an active layer comprising a quantum well structure;
a buffer layer underneath and adjacent to the active layer, wherein there is a lattice mismatch between the buffer layer and the active layer which places the active layer under biaxial compressive strain;
and means to apply uniaxial tensile strain to the active layer to reduce compressive strain on the active layer in a second direction but not in a first direction, the first direction and the second direction lying in a plane of the active layer.

2. Semiconductor device structure as claimed in claim 1, wherein a p-type device is formed in the semiconductor device structure, the p-type device having a p-channel oriented substantially in the first direction.

3. Semiconductor device structure as claimed in claim 2, wherein the p-type device is a p-FET.

4. Semiconductor device structure as claimed in claim 1, wherein an n-type device is formed in the semiconductor device structure, the n-type device having an n-channel oriented substantially in the first direction.

5. Semiconductor device structure as claimed in claim 4, wherein the n-type device is an n-FET.

6. Semiconductor device structure as claimed in claim 1, wherein the active layer is substantially unstrained in the second direction.

7. Semiconductor device structure as claimed in claim 1, wherein the active layer comprises an InSb quantum well structure.

8. Semiconductor device structure as claimed in claim 7, wherein the buffer layer is formed of AlₓIn₁₋ₓSb.

9. Semiconductor device structure as claimed in claim 1, wherein the means to apply uniaxial tensile strain comprises means to bend the semiconductor device structure about an axis lying in the first direction.

10. Semiconductor device structure as claimed in claim 1, wherein the means to apply uniaxial tensile strain comprises means to stretch the semiconductor device structure in the second direction.

11. Semiconductor device structure as claimed in claim 9, wherein the semiconductor device structure is bonded to a base substrate before or after bending or stretching.

12. A semiconductor structure as claimed in claim 1, wherein the uniaxial tensile strain is applied orthogonal to the direction of current flow in the active layer.

13. A method of manufacturing a semiconductor device structure, comprising:
epitaxially growing a buffer layer on a substrate;
epitaxially growing a quantum well active layer on the substrate, wherein there is a lattice mismatch between the buffer layer and the active layer which places the active layer under biaxial compressive strain; and
applying uniaxial tensile strain to the active layer to reduce compressive strain on the active layer in a second direction but not in a first direction, the first direction and the second direction lying in a plane of the active layer.

14. A method as claimed in claim 13, wherein the step of applying uniaxial tensile strain to the active layer comprises applying uniaxial tensile strain to the semiconductor device structure as a whole.

15. A method as claimed in claim 14, wherein the step of applying uniaxial tensile strain comprises bending the semiconductor device structure about an axis lying in the first direction before or after bonding the semiconductor device structure to a base substrate.

16. A method as claimed in claim 14, wherein the step of applying uniaxial tensile strain comprises stretching the semiconductor device structure in the second direction before or after bonding the semiconductor device structure to a base substrate.

17-18. (canceled)

19. Semiconductor device structure as claimed in claim 10, wherein the semiconductor device structure is bonded to a base substrate before or after bending or stretching.
